(19) United States
(12) Patent Application Publication
(10) Pub. No.: US 2003/0026075 A1
(43) Pub. Date: Feb. 6, 2003

(54) CPU heat sink with fan fitting hole

(76) Inventor: Ming-Long Lee, Taipei (TW)

Correspondence Address: RABIN & CHAMPAGNE, PC, 1101 14TH STREET, NW, SUITE 500, WASHINGTON, DC, 20005, US

(21) Appl. No.: 09/919,828

(22) Filed: Aug. 2, 2001

(51) Int. Cl. H05K 7/20; G06F 1/20

(52) U.S. Cl. 361/697; 361/687; 361/704

(57) ABSTRACT

A CPU heat sink with fan fitting hole includes a heat sink with a plurality numbers of vertical heat dissipating plates on top, the heat sink is fastened to a CPU socket with a fastener. A fan is mounted on top of the heat sink. The vertical heat dissipating plates of the heat sink has a fitting hole on top center; a plurality numbers of bases are equipped on the bottom of the fan. The fastener spans over the vertical heat dissipating plates and fixes the heat sink firmly first, then the fan is fixed on the bottom of the fitting hole of the heat sink by screws pass through the bases. Such scheme can reduce the height of the whole structure; the heat dissipation effect can be more efficiency.

### BACKGROUND OF THE INVENTION

I. Field of the Invention

This invention relates generally to a CPU (Central Processing Unit) heat sink with fan fitting hole and, more specifically, to a CPU heat sink that has a fan fitting hole in the middle of the vertical heat dissipation plate area. The fan is installed and fixed on the bottom of the fitting hole to blow cool air to the heat sink and lower the CPU temperature. The height and physical size of the whole structure can be reduced and have better heat dissipation effect.

II. Description of the Prior Art

It is known that the CPU of a computer generates heat while operating; the heat must be dissipated in order not to damage the CPU itself and have the CPU operate under normal working temperature.

The best way to dissipate the heat is to have a heat sink on top of the CPU, as shown in FIG. 4 and FIG. 5. The aluminum heat sink (a) has a plurality numbers of vertical heat dissipating plate (a1) and is fastened on the CPU socket (c) with a fastener (b). A fan (e) with outer frame is on top of the heat sink (a). The heat absorbed by the heat sink (a) is blown away by the fan (e) to keep CPU (d) working under normal temperature.

The speed of CPU (d) is getting faster and faster, the heat generated makes the temperature higher and higher, therefore the heat sink (a) of the CPU (d) must be more efficient to absorb and dissipate heat, otherwise the CPU (d) might be overheated and unable to function properly or even get damaged permanently.

In order to dissipate more heat, the most direct way is to enlarge the vertical heat dissipating plate (a1) of the heat sink (a). However increase the height of vertical heat dissipating plate (a1) results the total height of the heat sink (a) higher. Most of the known heat sink (a) adopt such scheme.

The fan (e) is mounted directly on top of the vertical heat dissipating plate (a1) that further increases the height and physical size of the heat sink (a), larger physical size increases the transportation cost.

### SUMMARY OF THE INVENTION

It is therefore a primary object of the invention to provide a CPU heat sink with fan fitting hole that hides the fan inside the heat dissipation plates to reduce the height and physical size, the transportation cost can be lowered and achieve better heat dissipation efficiency.

In order to achieve the objective set forth, a CPU heat sink with fan fitting hole in accordance with the present invention comprises of a heat sink with a plurality numbers of vertical heat dissipating plates on top, the heat sink is fastened to a CPU socket with a fastener. A fan is mounted on top of the heat sink; the heat generated by the CPU is absorbed by the heat sink, the fan blows cool air to dissipate the heat on the vertical heat dissipating plates of heat sink. The vertical heat dissipating plates of the heat sink has a fitting hole on top center; a plurality numbers of bases are equipped on the bottom of the fan. The fastener spans over the vertical heat dissipating plates and fixes the heat sink firmly first, then the fan is fixed on the bottom of the fitting hole of the heat sink by screws pass through the bases. Such scheme can reduce the height of the whole structure; the heat dissipation effect can be more efficiency.

### BRIEF DESCRIPTION OF THE DRAWINGS

The accomplishment of the above-mentioned object of the present invention will become apparent from the following description and its accompanying drawings which disclose illustrative an embodiment of the present invention, and are as follows:

FIG. 1 is a perspective view of the present invention;

FIG. 2 is an explosive view of the present invention;

FIG. 3 is a cross-sectional view of the present invention

FIG. 4 is a perspective view of the prior art;

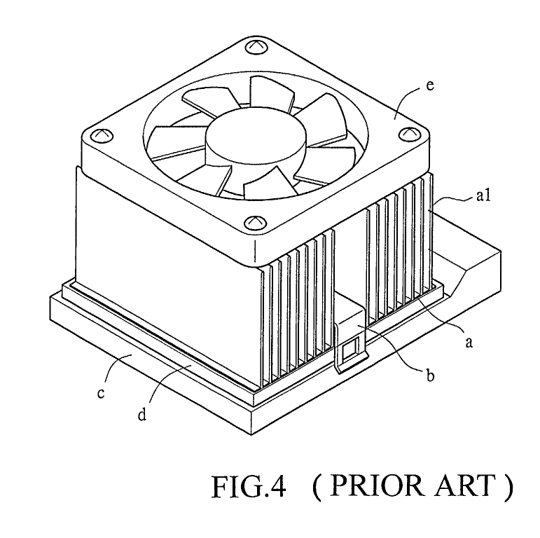

FIG. 5 is an explosive view of the prior art.

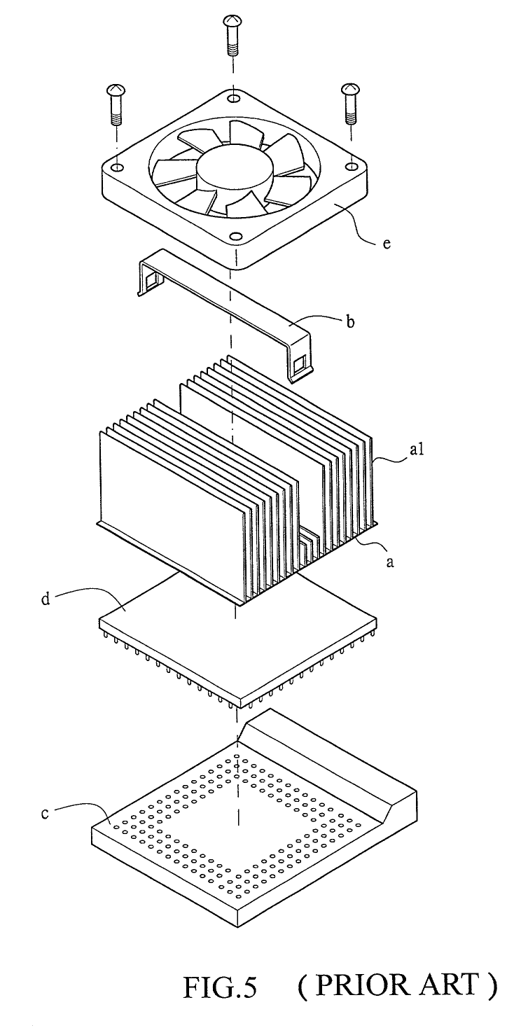

### DESCRIPTION OF THE PREFERRED EMBODIMENT

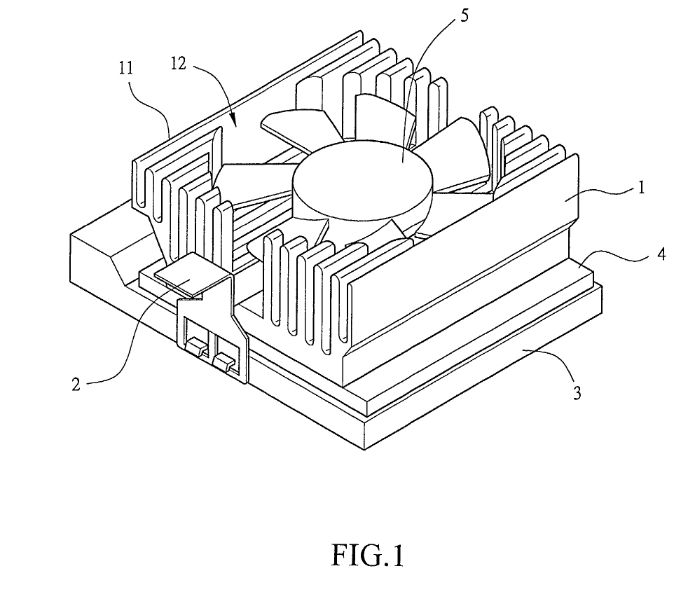

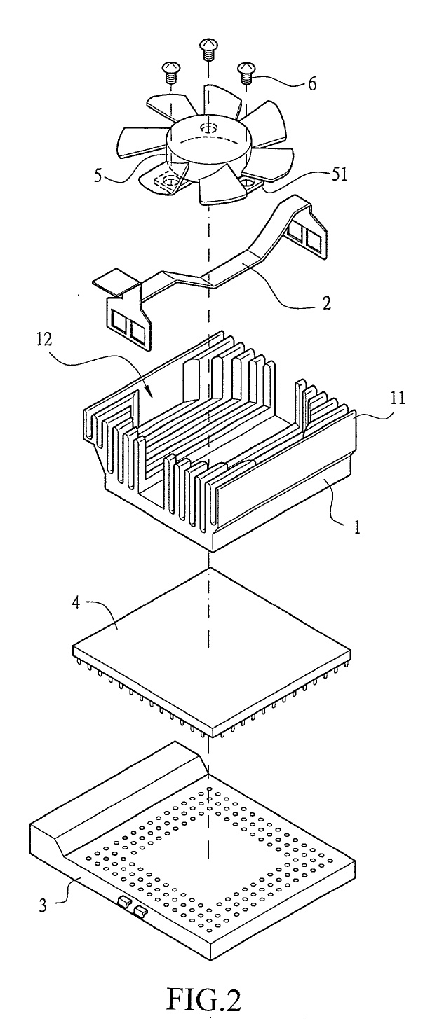

Referring to FIG. 1 and FIG. 2, the present invention is composed of a heat sink 1 with a plurality numbers of vertical heat dissipating plate 11 on top, the heat sink 1 is fastened to a CPU socket 3 with a fastener 2. A CPU 4 is installed between heat sink 1 and CPU socket 3. A fan 5 is mounted on top of the heat sink 1; the heat generated by the CPU 4 is absorbed by the heat sink 1, the fan 5 blows cool air to dissipate the heat on the vertical heat dissipating plate 11 of heat sink 1.

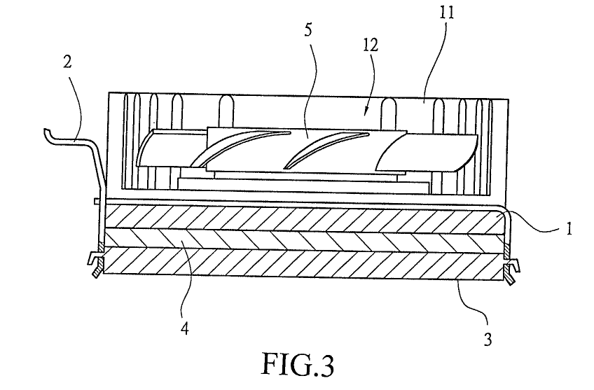

The vertical heat dissipating plate 11 of the heat sink 1 has a fitting hole 12 on top center; a plurality numbers of base 51 are equipped on the bottom of the fan 5. The fastener 2 spans over the vertical heat dissipating plate 11 and fixes the heat sink 1 firmly first, then the fan 5 is fixed on the bottom of the fitting hole 12 of the heat sink 1 by screw 6 passes through the base 51. Such scheme can reduce the height of the whole structure, as show in FIG. 3; the heat dissipation effect can be more efficiency.

Based on above structure, a fitting hole 12 is on top of the vertical heat dissipating plate 11 of the heat sink 1, the fan 5 does not have outer frame but is equipped with a plurality numbers of base 51 on the bottom. The fan 5 is fixed on the bottom of the fitting hole 12 by screw 6 passes through the base 51. The fan 5 is hidden inside the vertical heat dissipating plate 11 of the heat sink 1. The top of the heat sink 1 does not have other components, the height is lower and the whole physical size is smaller, as shown in FIG. 1 and FIG. 3, the transportation cost can be reduced.

The fan 5 is installed inside the vertical heat dissipating plate 11 of the heat sink 1, the cool air blown in by the fan 5 can bring the heat directly from the vertical heat dissipating plate 11, the cooling efficiency is better.

While a preferred embodiment of the invention has been shown and described in detail, it will be readily understood and appreciated that numerous omissions, changes and additions may be made without departing from the spirit and scope of the invention.

What is claimed is:

1. A CPU heat sink with fan fitting hole comprising:
a heat sink with a plurality numbers of vertical heat dissipating plates on top;
a fastener spanning over said vertical heat dissipating plates and fixing said heat sink to a CPU socket firmly;
a fan with a plurality numbers of bases on bottom being mounted on top of said heat sink with screws, said fan blows away the heat generated by the CPU and absorbed by said heat sink;
a fitting hole located on top center of said vertical heat dissipating plates of said heat sink to place said fan.
